(19) United States
(12) Patent Application Publication
(10) Pub. No.: US 2024/0069168 A1
(43) Pub. Date: Feb. 29, 2024

(54) SINGLE PHOTON DETECTION ELEMENT, ELECTRONIC DEVICE, AND LiDAR DEVICE

(71) Applicant: KOREA INSTITUTE OF SCIENCE AND TECHNOLOGY, Seoul (KR)

(72) Inventor: Myung-Jae LEE, Seoul (KR)

(21) Appl. No.: 18/308,202

(22) Filed: Apr. 27, 2023

(30) Foreign Application Priority Data
Aug. 24, 2022 (KR) 10-2022-0106211

(51) Int. Cl. G01S 7/481

(52) U.S. Cl. CPC G01S 7/4816

(57) ABSTRACT

Disclosed is a single photon detection device comprises a first well, a second well provided on the first well, a heavily doped region provided on the second well, and a contact facing the heavily doped region. The first well, the second well, and the contact have a first conductive type. The heavily doped region has a second conductive type that is different from the first conductive type. The region between the heavily doped region and the contact consist of semiconductor materials.

### CROSS-REFERENCE TO RELATED APPLICATIONS

This application claims priority under 35 U.S.C. § 119 to Korean Patent Application No. 10-2022-0106211 filed on Aug. 24, 2022, in the Korean Intellectual Property Office, the disclosures of which are incorporated by reference herein in their entireties.

### BACKGROUND

### 1. Technological Field

Embodiments of the present disclosure described herein relate to single photon detection element, electronic device, and LiDAR device.

The inventors acknowledge the financial support from the Korea Institute of Science and Technology (KIST) Institution Program (Grant No. 2E32242) and the National Research Foundation of Korea (NRF) (Grant No. 2021M3D1A2046731).

### 2. Description of the Related Art

The Avalanche Photodiode (APD) is a solid-stage light detector in which a high bias voltage is applied to the PN conjugation to provide a high first step gain from Avalanche Multiplication. When a photon with enough energy to release the electron reaches the photo diode, an electron-hole pair (EHP) is generated. The high electric field accelerates the photo-generated electrons quickly to (+) side, and the additional electrons-hole pairs are generated in succession by the impact ionization by such acceleration electrons. And then the electrons accelerate to the anode. Similarly, the holes are accelerated quickly toward (−) side and causes the same phenomenon. This process repeats the process leading to the Avalanche of the output current pulse and light generation electrons. Thus, APD is a semiconductor-based device that operates similarly to photomultiplier tubes. The linear mode APD is an effective amplifier that can control the bias voltage to set a gain and obtain tens of to thousands of gains in linear mode.

Single Photon Avalanche Diode (SPAD) is an APD in which the P-N bonding part is biased more than breakdown voltage to operate in the GEIGER mode. SPAD can generate a very large current, and as a result, a pulse signal that can be easily measured with a quenching resistor (or quenching circuit) can be obtained. That is, the SPAD operates as a device that generates a large pulse signal compared to the linear mode APD. After the triggering the Avalanche, the quenching resistance or the quenching circuit is used to reduce the bias voltage under the breakdown voltage for quenching the Avalanche process. Once the Avalanche Process is quenched, the bias voltage is rising back over the breakdown voltage so that the SPAD is reset for the detection of another photon. The above process can be referred to as re-biasing of SPAD.

SPAD can be configured with quenching resistance or circuit, recharge circuits, memory, gate circuits, counter, and time-digital converter. SPAD pixels are semiconductor-based, so it can be easily arrayed.

APD or SPAD may have a defect according to the manufacturing process. A defect in APD or SPAD can produce electrons. For example, electrons can be generated by defects according to the formation of the Shallow Trench Isolation (STI). The electrons generated by defects can be increased in a depletion region (or a multiplication region) in the APD or SPAD. As a result, noise signals may occur. In addition, the electrons generated by defects can be the cause of the after pulse phenomenon in which Avalanche occurs even though the photon is not incident on the APD or SPAD. If after pulse phenomenon is expected to occur, it may be necessary to increase the dead time, which is a preparation time for the APD or SPAD to detect one photon and the next photon, to prevent the impact. In some example embodiments, when the APD or SPAD operation, the frame rate or signal-to-noise ratio (SNR) may be reduced.

### SUMMARY

Embodiments of the present disclosure provide a single photon detection device, electronic device, and LiDAR device having a small noise and a short dead time. Embodiments of the present disclosure provide a single photon detection device, electronic device, and LiDAR device that reduces or prevents after-pulse phenomenon.

According to an embodiment, a single photon detection device comprises a first well, a second well provided on the first well, a heavily doped region provided on the second well, and a contact facing the heavily doped region, the first well, the second well, and the contact have a first conductive type. The heavily doped region has a second conductive type that is different from the first conductive type. The region between the heavily doped region and the contact consist of semiconductor materials.

According to further aspects of the invention, the distance between the heavily doped region and the contact is 0.2 [symbol] ˜2.5 [symbol] .

According to further aspects of the invention, the single photon detection device further comprises a guard ring provided between the heavily doped region and the contact, the guard ring has a second conductive type and has a doping concentration lower than the heavily doped region.

According to further aspects of the invention, the guard ring contacts with the heavily doped region.

According to further aspects of the invention, the guard ring extends to a side surface of the second well.

According to further aspects of the invention, a bottom surface of the guard ring is located at a depth between a bottom surface and an upper surface of the second well.

According to further aspects of the invention, a bottom surface of the guard ring is located at the same depth as a bottom surface of the second well.

According to further aspects of the invention, a bottom surface of the second well is located at a depth between an upper surface and a bottom surface of the guard ring.

According to further aspects of the invention, the first well extends to a region between the guard ring and the contact.

According to further aspects of the invention, the single photon detection device further comprises an isolation region provided on the opposite side of the guard ring with the contact interposed therebetween.

According to further aspects of the invention, the heavily doped region protrudes from a side of the second well.

According to further aspects of the invention, a side surface of the heavily doped region and a side surface of the second well forms a coplanar.

According to an embodiment, an electronic device comprises a single photon detection device including a first well, a second well provided on the first well, a heavily doped region provided on the second well, and a contact facing the heavily doped region. The first well, the second well, and the contact have a first conductive type. The heavily doped region has a second conductive type that is different from the first conductive type. A region between the heavily doped region and the contact consist of semiconductor materials.

According to an embodiment, a LiDAR device comprises electronic devices. The electronic device includes a single photon detection element. The single photon detection element includes a first well, a second well provided on the first well, a heavily doped region provided on the second well, and a contact facing the heavily doped region. The first well, the second well, and the contact have a first conductive type. The heavily doped region has a second conductive type that is different from the first conductive type. The region between the heavily doped region and the contact consist of semiconductor materials.

### BRIEF DESCRIPTION OF THE FIGURES

The above and other objects and features of the present disclosure will become apparent by describing in detail embodiments thereof with reference to the accompanying drawings.

FIG. 1 is a plan view of a single photon detection device according to an exemplary embodiment.

FIG. 2 is a cross-sectional view of the single photon detection device of FIG. 1 taken along line A-A′.

FIG. 3 is a plan view of the single photon detection device of FIG. 2 according to an exemplary embodiment.

FIG. 4 is a plan view of the single photon detection device of FIG. 2 according to an exemplary embodiment.

FIG. 5 is a plan view of the single photon detection device of FIG. 2 according to an exemplary embodiment.

FIG. 6 is a plan view of the single photon detection device of FIG. 2 according to an exemplary embodiment.

FIG. 7 is a plan view of the single photon detection device of FIG. 2 according to an exemplary embodiment.

FIG. 8 is a plan view of the single photon detection device of FIG. 2 according to an exemplary embodiment.

FIG. 9 is a cross-sectional view corresponding to line A-A′ of the single photon detection device of FIG. 1.

FIG. 10 is a cross-sectional view corresponding to line A-A′ of the single photon detection device of FIG. 1.

FIG. 11 is a cross-sectional view corresponding to line A-A′ of the single photon detection device of FIG. 1.

FIG. 12 is a cross-sectional view corresponding to line A-A′ of the single photon detection device of FIG. 1.

FIG. 13 is a cross-sectional view corresponding to line A-A′ of the single photon detection device of FIG. 1.

FIG. 14 is a cross-sectional view corresponding to line A-A′ of the single photon detection device of FIG. 1.

FIG. 15 is a cross-sectional view corresponding to line A-A′ of the single photon detection device of FIG. 1.

FIG. 16 is a cross-sectional view corresponding to line A-A′ of the single photon detection device of FIG. 1.

FIG. 17 is a plan view of a single photon detection device according to an exemplary embodiment.

FIG. 18 is a cross-sectional view corresponding to line B-B′ of the single photon detection device of FIG. 17.

FIG. 19 is a plan view of a single photon detection device according to an exemplary embodiment.

FIG. 20 is a cross-sectional view corresponding to line C-C′ of the single photon detection device of FIG. 19.

FIG. 21 is a plan view of a single photon detection device according to an exemplary embodiment.

FIG. 22 is a cross-sectional view corresponding to line D-D′ of the single photon detection device of FIG. 21.

FIG. 23 is a plan view of a single photon detection device according to an exemplary embodiment.

FIG. 24 is a cross-sectional view corresponding to the line E-E′ of the single photon detection device of FIG. 23.

FIG. 25 is a plan view of a single photon detection device according to an exemplary embodiment.

FIG. 26 is a cross-sectional view corresponding to line F-F′ of the single photon detection device of FIG. 25.

FIG. 27 is a cross-sectional view corresponding to line F-F′ of the single photon detection device of FIG. 25.

FIG. 28 is a plan view of a single photon detection device according to an exemplary embodiment.

FIG. 29 is a cross-sectional view corresponding to the line G-G′ of the single photon detection device of FIG. 28.

FIG. 30 is a cross-sectional view of a single photon detection device according to an exemplary embodiment.

FIG. 31 is a cross-sectional view of a single photon detector according to an exemplary embodiment.

FIG. 32 is a cross-sectional view of a single photon detector according to an exemplary embodiment.

FIG. 33 is a cross-sectional view of a single photon detector according to an exemplary embodiment.

FIG. 34 is a top view of a single photon detector array according to an exemplary embodiment.

FIGS. 35, 36, and 37 are cross-sectional views taken along line H-H′ of FIG. 34.

FIG. 38 is a block diagram for describing an electronic device according to an exemplary embodiment.

FIGS. 39 and 40 are conceptual diagrams illustrating cases in which a LiDAR device according to an exemplary embodiment is applied to a vehicle.

### DETAILED DESCRIPTION

Hereinafter, with reference to the accompanying drawings, the embodiments of the present disclosure will be described in detail. In the following drawings, the same reference code refers to the same component, and the size of each component in the drawings may be exaggerated for the clarity and convenience of the description. On the other hand, the embodiments described below are only an example, and various variations are possible from these embodiments.

Hereinafter, what is described as “on” may include not only being directly on contact but also being on non-contact.

Singular expressions include plural expressions unless the context clearly dictates otherwise. In addition, when a certain component is said to “include”, this means that it may further include other components without excluding other components unless otherwise stated.

In addition, terms such as “unit” or “part” described in the specification mean a unit that processes at least one function or operation.

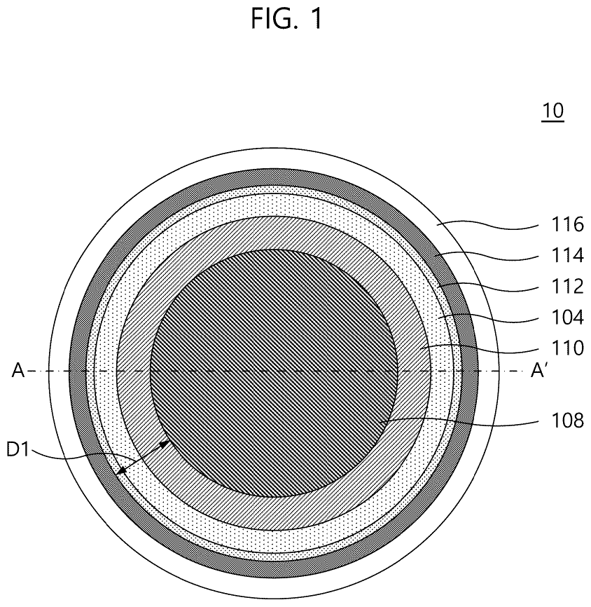

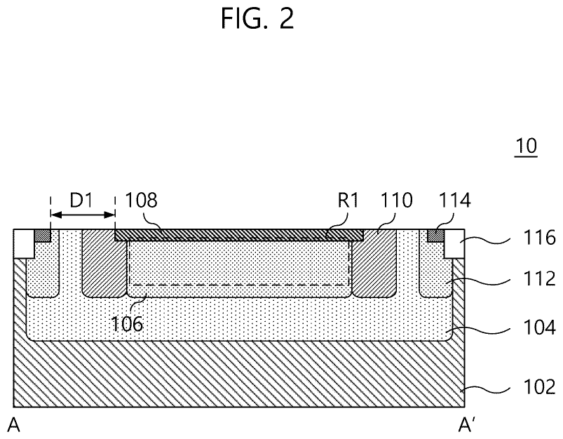

FIG. 1 is a plan view of a single photon detection device according to an exemplary embodiment. FIG. 2 is a cross-sectional view of the single photon detection device of FIG. 1 taken along line A-A′.

Referring to FIGS. 1 and 2, a single photon detection device 10 may be provided. The single photon detection device 10 may be a single photon avalanche diode (SPAD). A single photon avalanche diode (SPAD) may be referred to as a Geiger-mode avalanche diode (G-APD). The single photon detection device 10 may include a substrate region 102, a first well 104, a second well 106, a heavily doped region 108, a guard ring 110, a relief region 112, a contact 114, and an isolation region 116. The first well 104, the second well 106, the heavily doped region 108, the guard ring 110, the relief region 112, and the contact 114 are formed on a semiconductor substrate (eg, silicon (Si) substrate), which may be formed by implanting impurities. The isolation region 116 may be formed by, for example, a process of filling an insulating material in a recess region formed by etching a semiconductor substrate. The isolation region 116 may be shallow trench isolation (STI). In one example, in a CMOS process of approximately 180 nm to 250 nm or less, shallow trench isolation (STI) is automatically generated between adjacent active regions, and the isolation region 116 may be STI. The substrate region 102 may be the rest of the semiconductor substrate except for the first well 104, the second well 106, a heavily doped region 108, a guard ring 110, a relief region 112, the contact 114, and the isolation region 116.

The substrate region 102 may include silicon (Si), germanium (Ge), or silicon germanium (SiGe). The conductivity type of the substrate region 102 may be n-type or p-type. When the conductivity type of the substrate region 102 is n-type, the substrate region 102 may include a group 5 element (eg, phosphorus (P), arsenic (As), antimony (Sb), etc.), group 6 or group 7 element as an impurity. Hereinafter, a region having an n-type conductivity may include a group 5, 6, or 7 element as an impurity. When the conductivity type of the substrate region 102 is p-type, the substrate region 102 may include a group 3 element (eg, boron (B), aluminum (Al), gallium (Ga), indium (In), etc.) or 2 Group elements as impurities. Hereinafter, a region having a p-type conductivity may include a group 3 or group 2 element as an impurity. For example, the doping concentration of the substrate region 102 may be 1×10¹⁴ to 1×10¹⁹ cm⁻³. The semiconductor substrate may be an epi layer formed by an epitaxial growth process.

The first well 104 may be provided on the substrate region 102. The first well 104 may directly contact with the substrate region 102. The first well 104 may have a first conductivity type. For example, the conductivity type of the first well 104 may be n-type or p-type. For example, the doping concentration of the first well 104 may be 1×10¹⁴ to 1×10¹⁹ cm⁻³. In one example, the doping concentration of the first well 104 can vary continuously within the first well 104. For example, the doping concentration of the first well 104 may decrease as it is closer to the top surface of the single photon detection device 10. In one example, the first well 104 may have a uniform doping concentration. Although the top surface of the first well 104 is shown to be disposed to substantially the same height as the top surface of the single photon detection device 10, this is not limiting. In another example, the top surface of the first well 104 may be below the top surface of the single photon detection device 10(e.g., at a height between the top surface of the single photon detection device 10 and the bottom surface of the second well 106) can be placed.

The second well 106 may be provided on the first well 104. The second well 106 may directly contact with the first well 104. The second well 106 may have a first conductivity type. In one example, the doping concentration of the second well 106 may be uniform. In one example, the doping concentration of the second well 106 can vary continuously within the second well 106. For example, the doping concentration of the second well 106 may be 1×10¹⁴ to 1×10¹⁹ cm⁻³. The doping concentration may vary discontinuously at the boundary between the first well 104 and the second well 106.

A heavily doped region 108 may be provided on the second well 106. The heavily doped region 108 may be provided on the top surface of the second well 106. The heavily doped region 108 may contact the second well 106. A width of the heavily doped region 108 may be greater than that of the second well 106. The width of the heavily doped region 108 and the second well 106 may be the size of the heavily doped region 108 and the second well 106 along a direction parallel to the top surface of the substrate. An end portion of the heavily doped region 108 may protrude from side surfaces of the second well 106. The heavily doped region 108 may be exposed between guard rings 110 to be described below. The heavily doped region 108 may have a second conductivity type different from the first conductivity type. For example, the doping concentration of the heavily doped region 108 may be 1×10¹⁵ to 1×10²² cm⁻³. When the single photon detection device 10 is a single photon avalanche diode (SPAD), the heavily doped region 108 may be electrically connected to at least one of a quenching resistor (or quenching circuit) and other pixel circuits. A quenching resistor or quenching circuit may be configured to stop the avalanche effect and allow the single photon avalanche diode (SPAD) to detect another photon. Other pixel circuits may include, for example, reset or recharge circuits, memories, amplifier circuits, counters, gate circuits, time-to-digital converters, and the like. Other pixel circuits may transmit signals to the single photon detection device 10 or receive signals from the single photon detection device 10. In one example, the heavily doped region 108 may be electrically connected to an external power source or an integrated power source(eg, DC-to-DC converter, a charge pump, a boost converter, and other power management integrated circuits).

A depletion region R1 may be formed in a region adjacent to an interface between the second well 106 and the heavily doped region 108. The size of the depletion region R1 is shown as an example, and is not limited. When a reverse bias is applied to the single photon detection device 10, a strong electric field may be formed in the depletion region R1. For example, when the single photon detection device 10 operates as a single photon avalanche diode (SPAD), the maximum magnitude of the electric field may be about 1×10⁵ to 1×10⁶ V/cm. Since electrons may be multiplied by the electric field of the depletion region R1, the depletion region R1 may be referred to as a multiplication region.

The guard ring 110 may be provided on side surfaces of the heavily doped region 108 and side surfaces of the second well 106. The guard ring 110 may surround the heavily doped region 108 and the second well 106. For example, the guard ring 110 may have a ring shape extending along the side surfaces of the heavily doped region 108 and the side surfaces of the second well 106. The guard ring 110 may directly contact with the heavily doped region 108 and the second well 106. In another example, the guard ring 110 may be apart from the heavily doped region 108 and the second well 106. An top surface of the guard ring 110 may be disposed at substantially the same height as an top surface of the heavily doped region 108. The bottom surface of the guard ring 110 may be disposed at substantially the same height as the bottom surface of the second well 106. The guard ring 110 may have a second conductivity type. The doping concentration of the guard ring 110 may be lower than that of the heavily doped region 108. For example, the doping concentration of the guard ring 110 may be 1×10¹⁵ to 1×10¹⁸ cm⁻³. The guard ring 110 may improve breakdown characteristics of the single photon detection device 10. In detail, the guard ring 110 may relieve concentration of an electric field at the edge of the heavily doped region 108 to prevent premature breakdown. The early breakdown phenomenon is a breakdown phenomenon that occurs at the corner of the heavily doped region 108 before an electric field having sufficient magnitude is applied to the depletion region R1. The early breakdown phenomenon occurs as the electric field is concentrated at the corner of the highly doped region 108.

The contact 114 may be provided on the first well 104. The contact 114 may be electrically connected to a circuit outside the single photon detection device 10. When the single photon detection device 10 is a single photon avalanche diode (SPAD), the contact 114 may be electrically connected to at least one of an external power supply and an integrated power source(eg, DC-to-DC converter, a charge pump, a boost converter, and other power management integrated circuits). In one example, contact 114 may be electrically connected to at least one of a quenching resistor (or quenching circuit) and other pixel circuitry. A quench resistor or quench circuit may stop the avalanche effect and allow the single photon avalanche diode (SPAD) to detect another photon. Other pixel circuits may include, for example, reset or recharge circuits, memories, amplifier circuits, counters, gate circuits, time-to-digital converters, and the like. Other pixel circuits may transmit signals to the single photon detection device 10 or receive signals from the single photon detection device 10. The contact 114 may be provided on the opposite side of the heavily doped regions 108 with the guard ring 110 interposed therebetween. The contact 114 may surround the guard ring 110. In another example, a plurality of contacts 114 may be provided. In some example embodiments, the plurality of contacts 114 may be electrically connected to an external circuit of the single photon detection device 10, respectively. The contact 114 may have a first conductivity type. A doping concentration of the contact 114 may be higher than that of the first well 104. For example, the doping concentration of the contact 114 may be 1×10¹⁵ to 1×10²² cm⁻³.

A relief region 112 may be provided between the contact 114 and the first well 104. The relief region 112 may be electrically connected to the contact 114 and the first well 104. The relief region 112 may relieve a difference in doping concentration between the contact 114 and the first well 104. The relief region 112 may improve electrical connection characteristics between the contact 114 and the first well 104. For example, the relief region 112 is configured to reduce or prevent a voltage drop when a voltage is applied to the first well 104 through the contact 114 and to uniformly apply the voltage to the first well 104. Relief region 112 may extend along contact 114. The relief region 112 may be provided on side and bottom surfaces of the contact 114. For example, the relief region 112 may directly contact side and bottom surfaces of the contact 114. The relief region 112 may surround the guard ring 110. The relief region 112 may be apart from the guard ring 110. The first well 104 may extend to a region between the relief region 112 and the guard ring 110. For example, a region between the relief region 112 and the guard ring 110 may be filled with the first well 104. In one example, a region between the relief region 112 and the guard ring 110 may be filled with the substrate region 102 and the first well 104. The relief region 112 may be formed to the same depth as the bottom surface of the guard ring 110. In another example, the relief region 112 may be formed to a depth deeper than or shallower than the bottom surface of the guard ring 110. The relief region 112 may have a first conductivity type. The doping concentration of the relief region 112 may be lower than that of the contact 114 and may be similar to or higher than the doping concentration of the first well 104. For example, the doping concentration of the relief region 112 may be 1×10¹⁵ to 1×10¹⁹ cm⁻³.

When several active regions (eg, p+ region and n+ region) are formed during semiconductor device design, Shallow Trench Isolation (STI) is automatically generated between adjacent active regions in a CMOS process of approximately 180 nm to 250 nm or less. For example, STI between the contact 114 and the heavily doped region 108 may be automatically generated. STI can often create defects in substrates. The defects generated by STI between the contact 114 and the heavily doped region 108 may cause a dark count rate and an after pulse phenomenon. The present disclosure may provide the single photon detection device 10 configured such that no STI is intentionally formed between the contact 114 and the heavily doped region 108. Accordingly, noise and after pulse phenomena may be reduced or prevented. Accordingly, dead time, which is a preparation time for the APD or SPAD to detect the next photon after detecting one photon, can be reduced. When designing a semiconductor device, by intentionally forming an active layer between the p+ region and the n+ region, STI may not be intentionally formed between the contact 114 and the heavily doped region 108. In one example, the distance D1 between the contact 114 and the heavily doped region 108 may be 0.2 [symbol] to 2.5 [symbol] . In one example, the operation is possible even if the distance D1 between the contact 114 and the heavily doped region 108 is further increased, but there is a limit since the fill factor of the device may decrease. When the distance D1 between the contact 114 and the heavily doped region 108 is less than 0.2 [symbol] to 2.5 [symbol] , leakage current may occur.

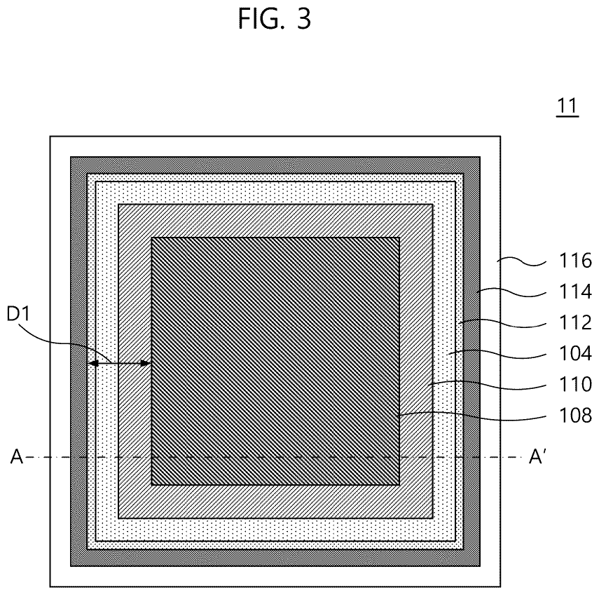

FIG. 3 is a plan view of the single photon detection device of FIG. 2 according to an exemplary embodiment. Differences from those shown in FIG. 1 are described for brevity of explanation.

Referring to FIG. 3, a single photon detection device 11 may be provided. Unlike that shown in FIG. 1, the single photon detection device 11 may have a square shape. Specifically, the heavily doped region 108 may have a square shape, and the guard ring 110, the first well 104, the relief region 112, the contact 114, and the isolation region 116 may have a square ring shape surrounding the heavily doped region 108. The guard ring 110, the first well 104, the relief region 112, the contact 114, and the isolation region 116 may be sequentially arranged in a direction away from the heavily doped region 108. For example, the guard ring 110, the first well 104, the relief region 112, the contact 114, and the isolation region 116 may have the same center.

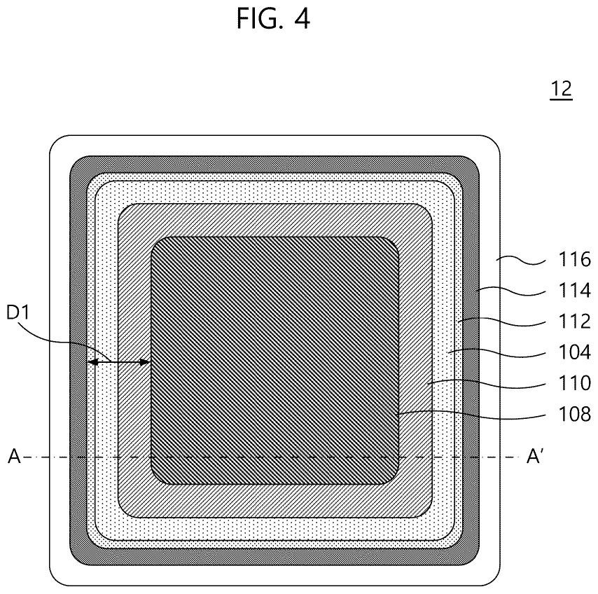

FIG. 4 is a plan view of the single photon detection device of FIG. 2 according to an exemplary embodiment. Differences from those shown in FIG. 1 are described for brevity of explanation.

Referring to FIG. 4, a single photon detection device 12 may be provided. Unlike that shown in FIG. 1, the single photon detection device 12 may have a square shape with rounded corners. Specifically, the heavily doped region 108 may have a square shape with rounded corners, and the guard ring 110, the first well 104, the relief region 112, the contact 114, and the isolation region 116 may have a square ring shape with rounded corners surrounding the heavily doped region 108. The guard ring 110, the first well 104, the relief region 112, the contact 114, and the isolation region 116 may be sequentially arranged in a direction away from the heavily doped region 108. For example, the heavily doped region 108, the guard ring 110, the first well 104, the relief region 112, the contact 114, and the isolation region 116 may have the same center.

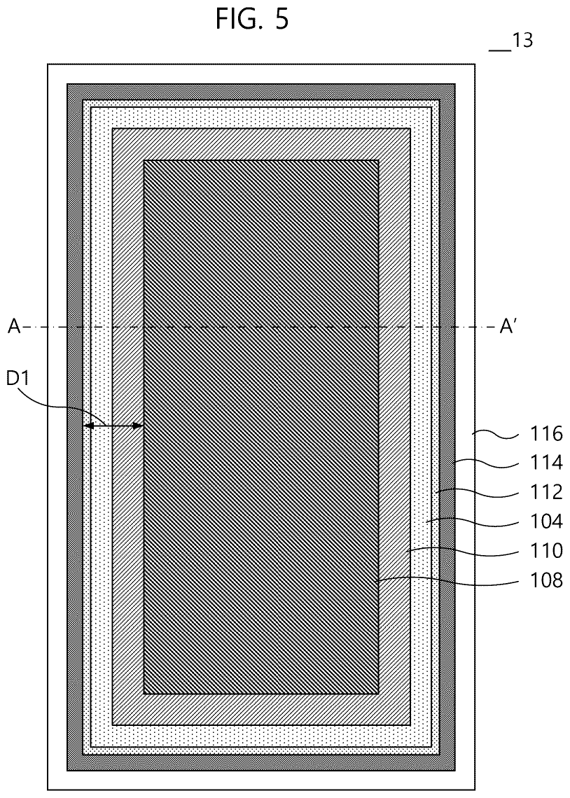

FIG. 5 is a plan view of the single photon detection device of FIG. 2 according to an exemplary embodiment. Differences from those shown in FIG. 1 are described for brevity of explanation.

Referring to FIG. 5, a single photon detection device 13 may be provided. Unlike that shown in FIG. 1, the single photon detection device 13 may have a rectangular shape. Specifically, the heavily doped region 108 may have a rectangular shape, and the guard ring 110, the first well 104, the relief region 112, the contact 114, and the isolation region 116 may have a rectangular ring shape surrounding the heavily doped region 108. The guard ring 110, the first well 104, the relief region 112, the contact 114, and the isolation region 116 may be sequentially arranged in a direction away from the heavily doped region 108. For example, the heavily doped region 108, the guard ring 110, the first well 104, the relief region 112, the contact 114, and the isolation region 116 may have the same center.

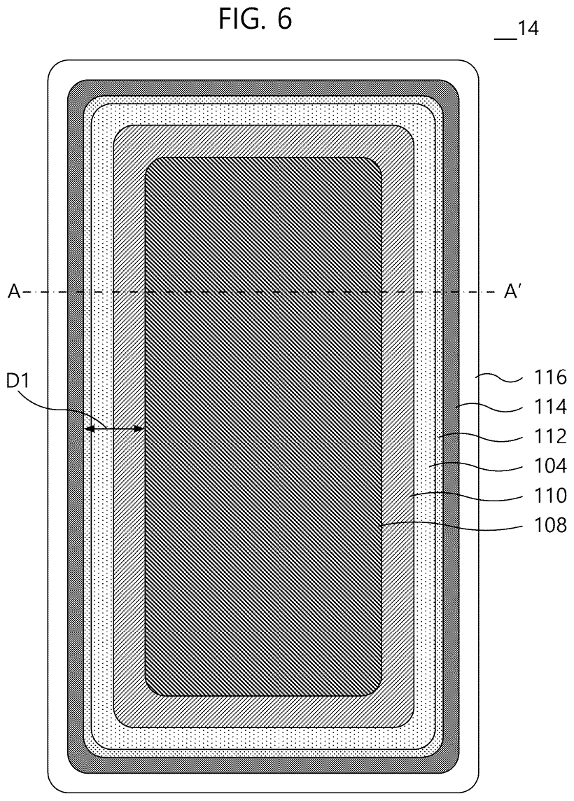

FIG. 6 is a plan view of the single photon detection device of FIG. 2 according to an exemplary embodiment. Differences from those shown in FIG. 1 are described for brevity of explanation.

Referring to FIG. 6, a single photon detection device 14 may be provided. Unlike that shown in FIG. 1, the single photon detection device 14 may have a rectangular shape with rounded corners. Specifically, the heavily doped region 108 may have a rectangular shape with rounded corners, and the guard ring 110, the first well 104, the relief region 112, the contact 114, and the isolation region 116 may have a rectangular ring shape with rounded corners surrounding the heavily doped region 108. The guard ring 110, the first well 104, the relief region 112, the contact 114, and the isolation region 116 may be sequentially arranged in a direction away from the heavily doped region 108. For example, the heavily doped region 108, the guard ring 110, the first well 104, the relief region 112, the contact 114, and the isolation region 116 may have the same center.

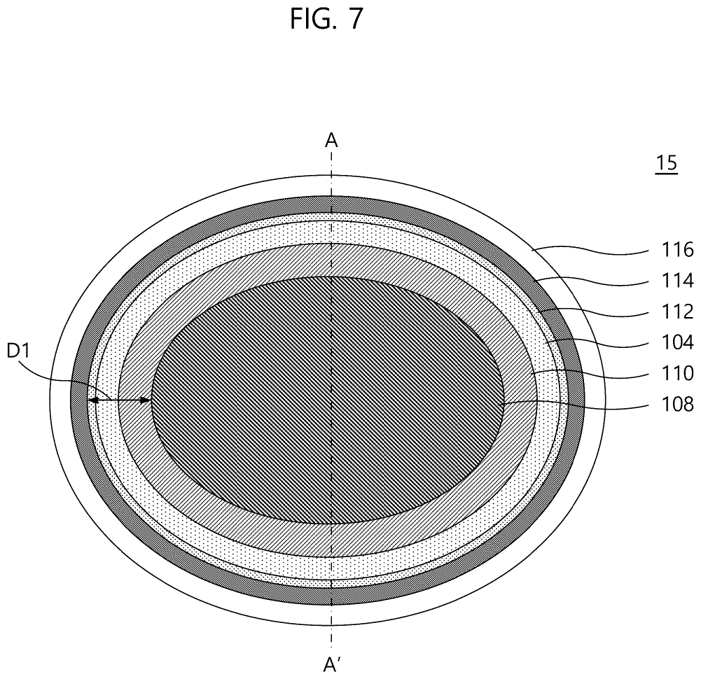

FIG. 7 is a plan view of the single photon detection device of FIG. 2 according to an exemplary embodiment. Differences from those shown in FIG. 1 are described for brevity of explanation.

Referring to FIG. 7, a single photon detection device 15 may be provided. Unlike that shown in FIG. 1, the single photon detection device 15 may have an elliptical shape. Specifically, the heavily doped region 108 may have an elliptical shape, and the guard ring 110, the relief region 112, the first well 104, the contact 114, and the isolation region 116 may have an elliptical ring shape surrounding the heavily doped region 108. The guard ring 110, the relief region 112, the first well 104, the contact 114, and the isolation region 116 may be sequentially arranged in a direction away from the heavily doped region 108. For example, the heavily doped region 108, the guard ring 110, the first well 104, the relief region 112, the contact 114, and the isolation region 116 may have the same center.

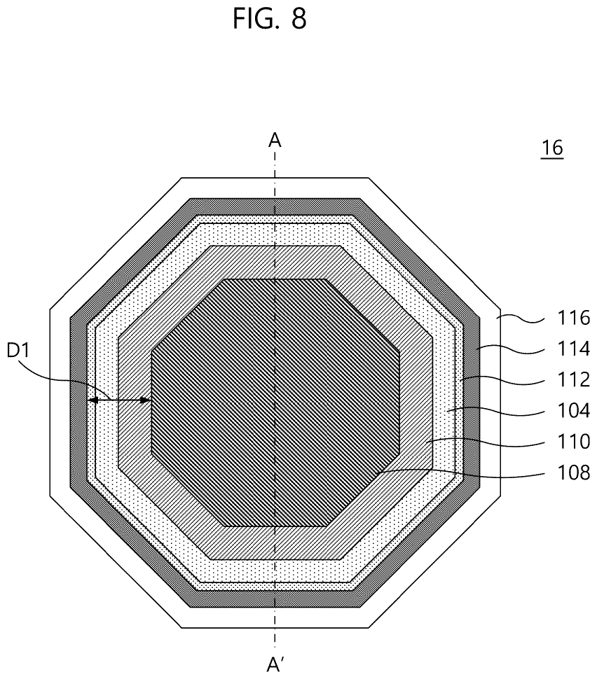

FIG. 8 is a plan view of the single photon detection device of FIG. 2 according to an exemplary embodiment. Differences from those shown in FIG. 1 are described for brevity of explanation.

Referring to FIG. 8, a single photon detection device 16 may be provided. Unlike that shown in FIG. 1, the single photon detection device 16 may have an octagonal shape. Specifically, the heavily doped region 108 may have an octagonal shape, and the guard ring 110, the relief region 112, the first well 104, the contact 114, and the isolation region 116 may have an octagonal ring shape surrounding the heavily doped region 108. The guard ring 110, the relief region 112, the first well 104, the contact 114, and the isolation region 116 may be sequentially arranged in a direction away from the heavily doped region 108. For example, the heavily doped region 108, the guard ring 110, the first well 104, the relief region 112, the contact 114, and the isolation region 116 may have the same center.

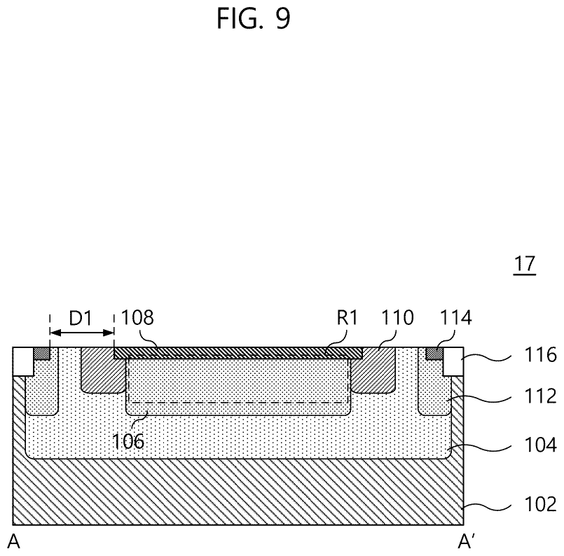

FIG. 9 is a cross-sectional view corresponding to line A-A′ of the single photon detection device of FIG. 1. Differences from those described with reference to FIGS. 1 and 2 are described for brevity of description.

Referring to FIG. 9, a single photon detection device 17 may be provided. Unlike the description with reference to FIGS. 1 and 2, the bottom surface of the guard ring 110 may be disposed at a height between the bottom surface and the top surface of the second well 106. The doping concentration of the guard ring 110 may be higher than that of the guard ring 110 described with reference to FIGS. 1 and 2. For example, the doping concentration of the guard ring 110 may be 1×10¹⁶ to 1×10¹⁸ cm⁻³.

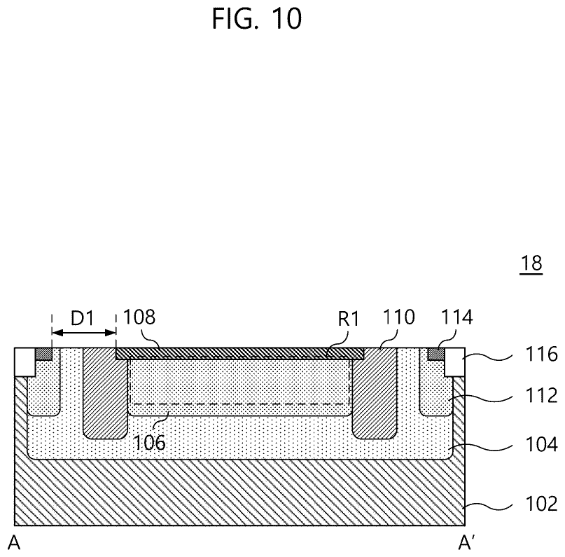

FIG. 10 is a cross-sectional view corresponding to line A-A′ of the single photon detection device of FIG. 1. Differences from those described with reference to FIGS. 1 and 2 are described for brevity of description.

Referring to FIG. 10, a single photon detection device 18 may be provided. Unlike the description with reference to FIGS. 1 and 2, the bottom surface of the second well 106 may be disposed at a height between the bottom surface and the top surface of the guard ring 110. The doping concentration of the guard ring 110 may be lower than that of the guard ring 110 described with reference to FIGS. 1 and 2. For example, the doping concentration of the guard ring 110 may be 1×10¹⁵ to 1×10¹⁷ cm⁻³.

In another example, unlike those described with reference to FIGS. 1 and 2, the second well 106 may have a second conductivity type. The doping concentration of the second well 106 may be lower than that of the heavily doped region 108 and higher than that of the guard ring 110. For example, the doping concentration of the second well 106 may be 1×10¹⁶ to 1×10¹⁸ cm⁻³. When the second well 106 has the second conductivity type, the depletion region R1 may be formed adjacent to the boundary between the second well 106 and the first well 104.

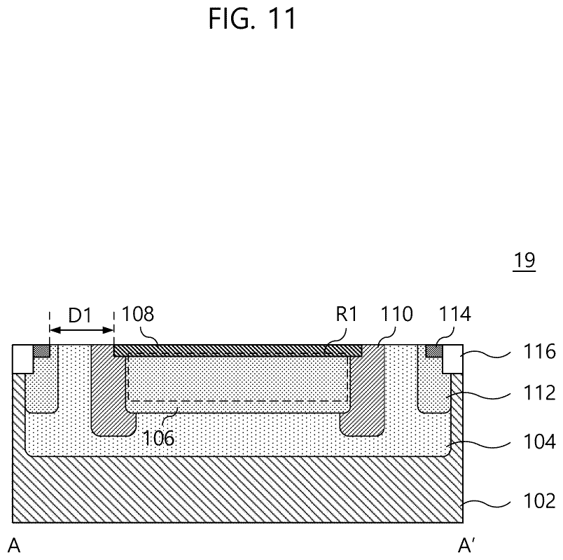

FIG. 11 is a cross-sectional view corresponding to line A-A′ of the single photon detection device of FIG. 1. Differences from those described with reference to FIGS. 1 and 2 are described for brevity of description.

Referring to FIG. 11, a single photon detection device 19 may be provided. Unlike those described with reference to FIGS. 1 and 2, the guard ring 110 may extend from a region on the side surface of the second well 106 to a region on the bottom surface of the second well 106. For example, the doping concentration of the guard ring 110 may be 1×10¹⁵ to 1×10¹⁸ cm⁻³.

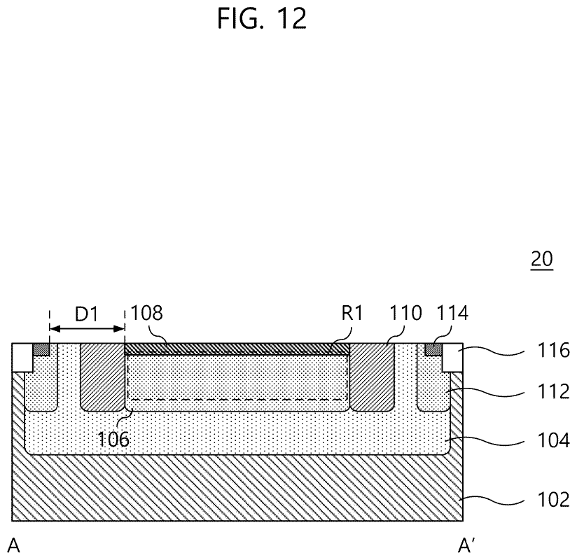

FIG. 12 is a cross-sectional view corresponding to line A-A′ of the single photon detection device of FIG. 1. Differences from those described with reference to FIGS. 1 and 2 are described for brevity of description.

Referring to FIG. 12, a single photon detection device 20 may be provided. Unlike the description with reference to FIGS. 1 and 2, a side surface of the heavily doped region 108 may be aligned with a side surface of the second well 106. A side surface of the heavily doped region 108 may be coplanar with a side surface of the second well 106. An end portion of the heavily doped region 108 may not protrude from a side surface of the second well 106.

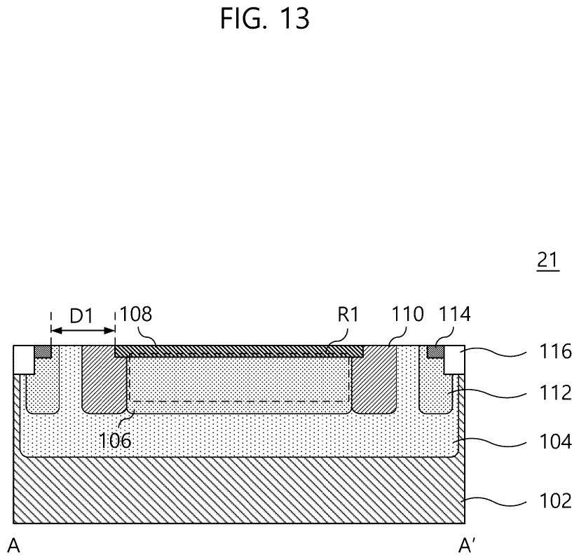

FIG. 13 is a cross-sectional view corresponding to line A-A′ of the single photon detection device of FIG. 1. Differences from those described with reference to FIGS. 1 and 2 are described for brevity of description.

Referring to FIG. 13, a single photon detection device 21 may be provided. Unlike those described with reference to FIGS. 1 and 2, the first well 104 may cover a side surface opposite to the side of the relief region 112 facing the guard ring 110 (hereinafter referred to as the outer surface of the relief region 112). The outer surface of the relief region 112 may be apart from the substrate region 102 with the first well 104 therebetween.

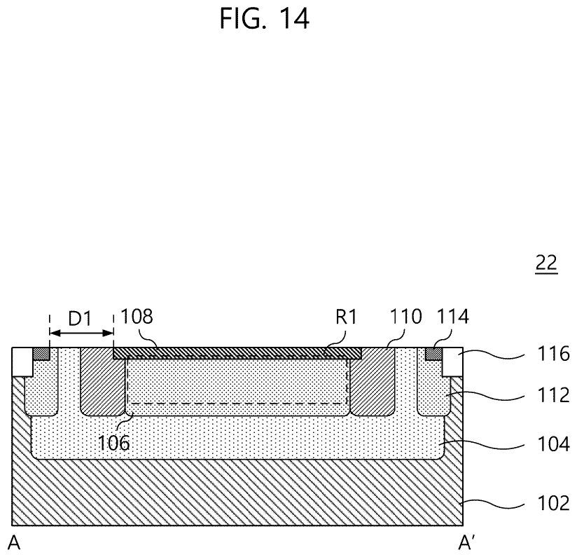

FIG. 14 is a cross-sectional view corresponding to line A-A′ of the single photon detection device of FIG. 1. Differences from those described with reference to FIGS. 1 and 2 are described for brevity of description.

Referring to FIG. 14, a single photon detection device 22 may be provided. Unlike the description with reference to FIGS. 1 and 2, the relief region 112 may protrude from the side of the first well 104. The substrate region 102 may cover an outer surface and a bottom surface of the relief region 112.

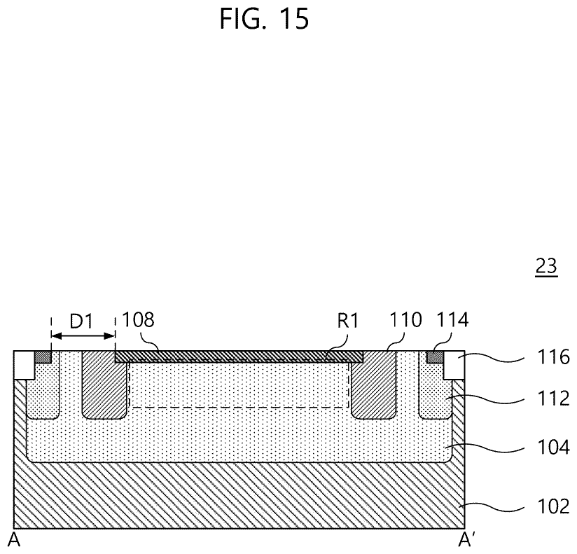

FIG. 15 is a cross-sectional view corresponding to line A-A′ of the single photon detection device of FIG. 1. Differences from those described with reference to FIGS. 1 and 2 are described for brevity of description.

Referring to FIG. 15, a single photon detection device 23 may be provided. Unlike the description with reference to FIGS. 1 and 2, the second well 106 is not provided between the heavily doped region 108 and the first well 104, and the first well 104 may directly contact with the heavily doped region 108.

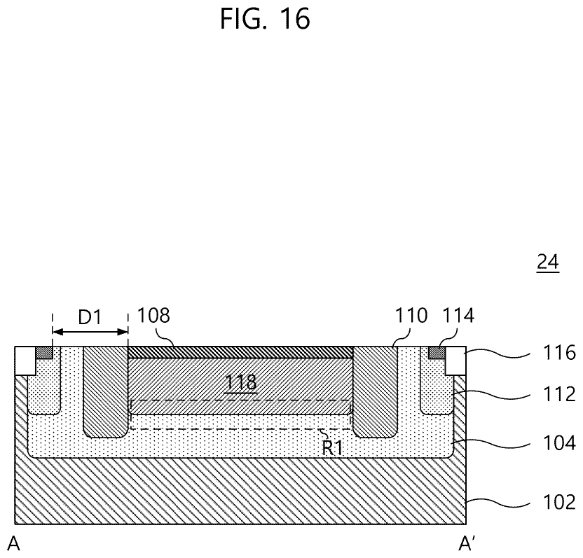

FIG. 16 is a cross-sectional view corresponding to line A-A′ of the single photon detection device of FIG. 1. Differences from those described with reference to FIGS. 1 and 2 are described for brevity of description.

Referring to FIG. 16, a single photon detection device 24 may be provided. Unlike the description with reference to FIGS. 1 and 2, a third well 118 may be provided between the first well 104 and the heavily doped region 108. The second well 106 may not be provided. The third well 118 may separate the heavily doped region 108 and the first well 104 from each other. The third well 118 may be provided on the bottom surface of the heavily doped region 108. A side surface of the third well 118 and a side surface of the heavily doped region 108 may be aligned. A side surface of the third well 118 and a side surface of the heavily doped region 108 may form a coplanar surface. The third well 118 may have the second conductivity type. The doping concentration of the third well 118 may be lower than that of the heavily doped region 108 and higher than that of the guard ring 110. For example, the doping concentration of the third well 118 may be 1×10¹⁶ to 1×10¹⁸ cm⁻³. The depletion region R1 may be formed adjacent to a boundary between the third well 118 and the first well 104.

The guard ring 110 may extend from the top surface of the single photon detection device 24 to a position deeper than the bottom surface of the third well 118. The bottom surface of the guard ring 110 may be disposed closer to the bottom surface of the first well 104 than the bottom surface of the third well 118. The guard ring 110 may have a lower doping concentration than that of the third well 118. For example, the doping concentration of the guard ring 110 may be 1×10¹⁵ to 1×10¹⁷ cm⁻³.

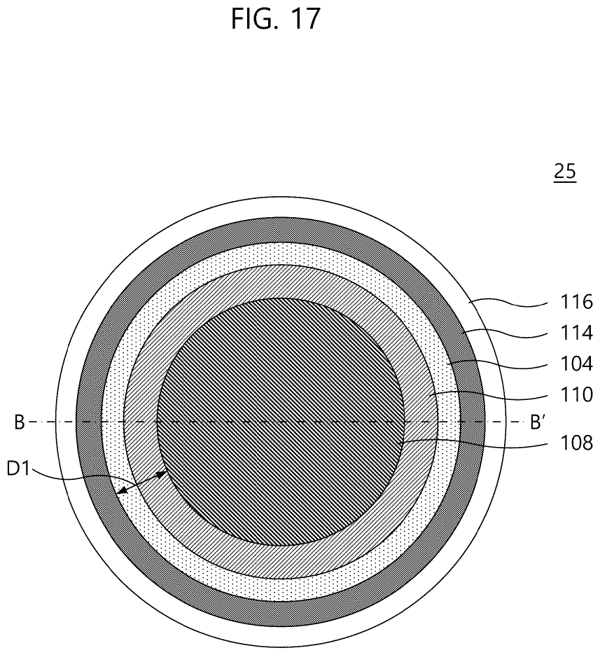

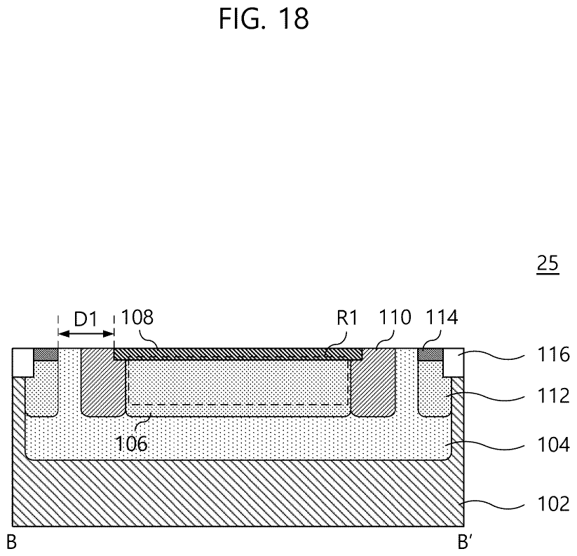

FIG. 17 is a plan view of a single photon detection device according to an exemplary embodiment. FIG. 18 is a cross-sectional view corresponding to line B-B′ of the single photon detection device of FIG. 17. Differences from those described with reference to FIGS. 1 and 2 are described for brevity of description.

Referring to FIGS. 17 and 18, a single photon detection device 25 may be provided. Unlike what has been described with reference to FIGS. 1 and 2, a side surface of the contact 114 may be aligned with a side surface of the relief region 112. In other words, the side surface of the contact 114 and the side surface of the relief region 112 may form a coplanar surface. The side surface of the contact 114 may directly contact with the first well 104 and the isolation region 116. A bottom surface of the contact 114 may directly contact with the relief region 112.

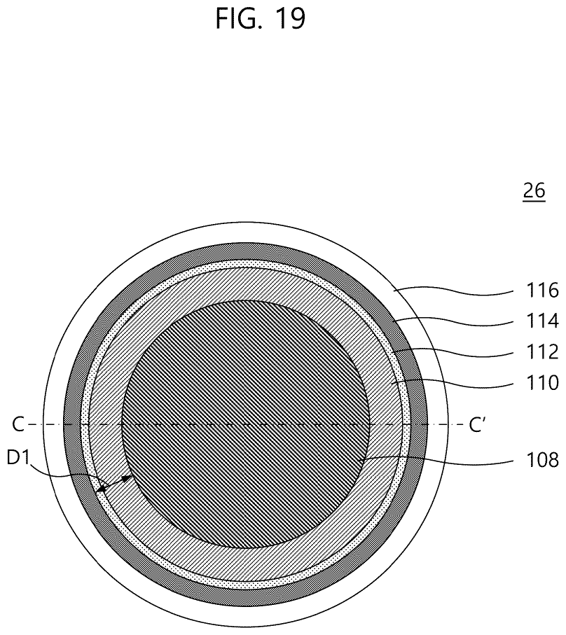

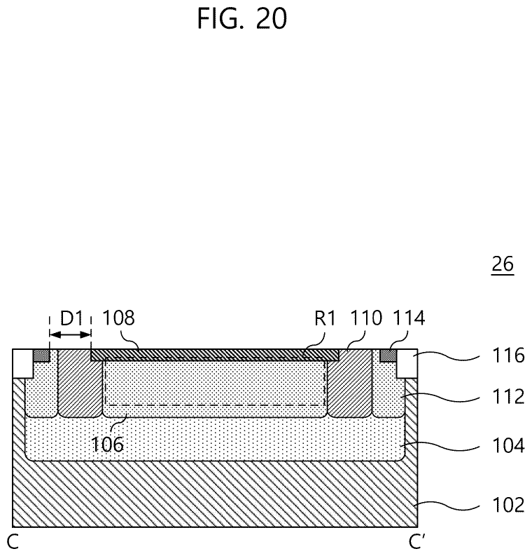

FIG. 19 is a plan view of a single photon detection device according to an exemplary embodiment. FIG. 20 is a cross-sectional view corresponding to line C-C′ of the single photon detection device of FIG. 19. Differences from those described with reference to FIGS. 1 and 2 are described for brevity of description.

Referring to FIGS. 19 and 20, a single photon detection device 26 may be provided. Unlike the description with reference to FIGS. 1 and 2, the guard ring 110 may directly contact with the relief region 112. For example, the guard ring 110 may fill a region between the relief region 112 and the second well 106 and a region between the relief region 112 and the heavily doped region 108. As shown in FIG. 9, when the bottom surface of the guard ring 110 is located at a height between the top surface and the bottom surface of the second well 106, the guard ring 110 may fill a portion of the region between the relief region 112 and the second well 106, and the first well 104 may fill another portion of the region between the relief region 112 and the second well 106.

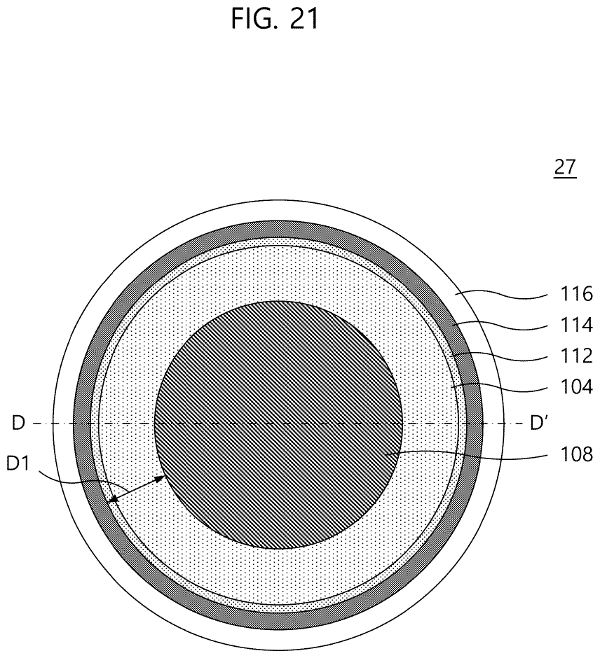

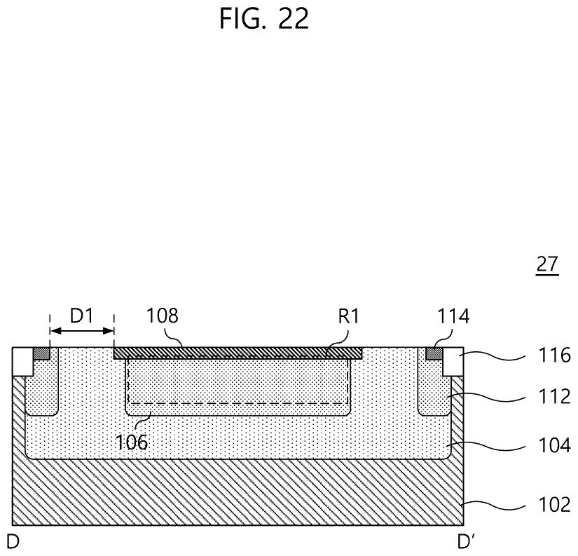

FIG. 21 is a plan view of a single photon detection device according to an exemplary embodiment. FIG. 22 is a cross-sectional view corresponding to line D-D′ of the single photon detection device of FIG. 21. Differences from those described with reference to FIGS. 1 and 2 are described for brevity of description.

Referring to FIGS. 21 and 22, a single photon detection device 27 may be provided. Unlike the description with reference to FIGS. 1 and 2, regions between the heavily doped region 108 and the relief region 112 and between the second well 106 and the relief region 112 may be filled with the first well 104. The heavily doped region 108 may directly contact with the first well 104. The guard ring 110 may not be provided.

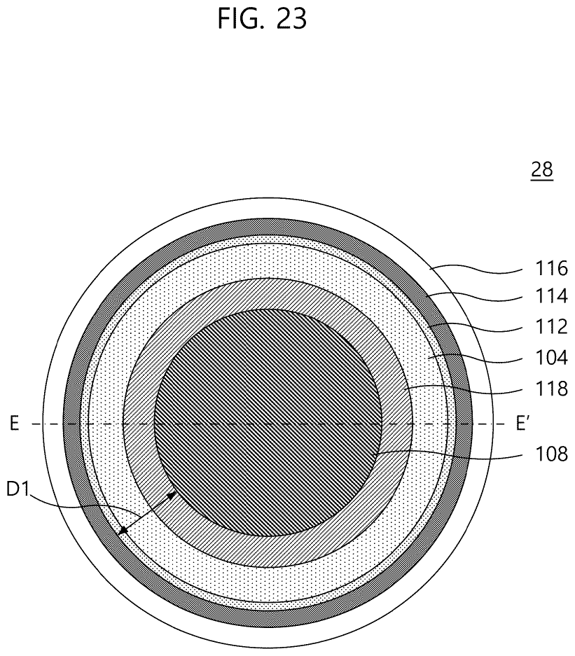

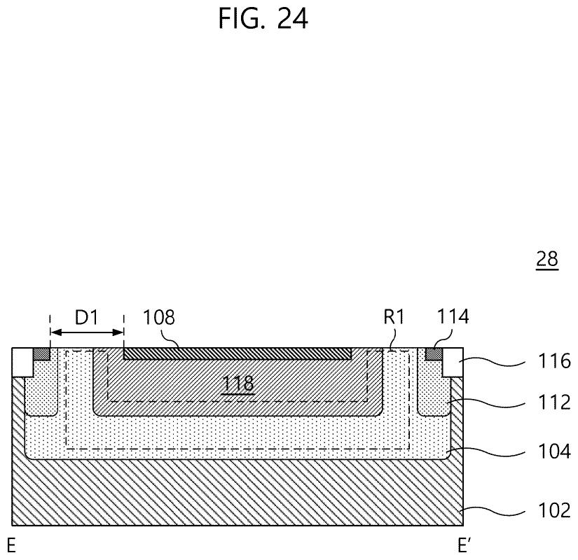

FIG. 23 is a plan view of a single photon detection device according to an exemplary embodiment. FIG. 24 is a cross-sectional view corresponding to the line E-E′ of the single photon detection device of FIG. 23. Differences from those described with reference to FIGS. 1 and 2 are described for brevity of description.

Referring to FIGS. 23 and 24, a single photon detection device 28 may be provided. Unlike the description with reference to FIGS. 1 and 2, a third well 118 may be provided between the first well 104 and the heavily doped region 108. The second well 106 and the guard ring 110 may not be provided. The third well 118 may separate the heavily doped region 108 and the first well 104 from each other. The third well 118 may have a second conductivity type. The doping concentration of the third well 118 may be lower than that of the heavily doped region 108. For example, the doping concentration of the third well 118 may be 1×10¹⁶ to 1×10¹⁸ cm⁻³. The depletion region R1 may be formed in a region adjacent to a boundary between the third well 118 and the first well 104.

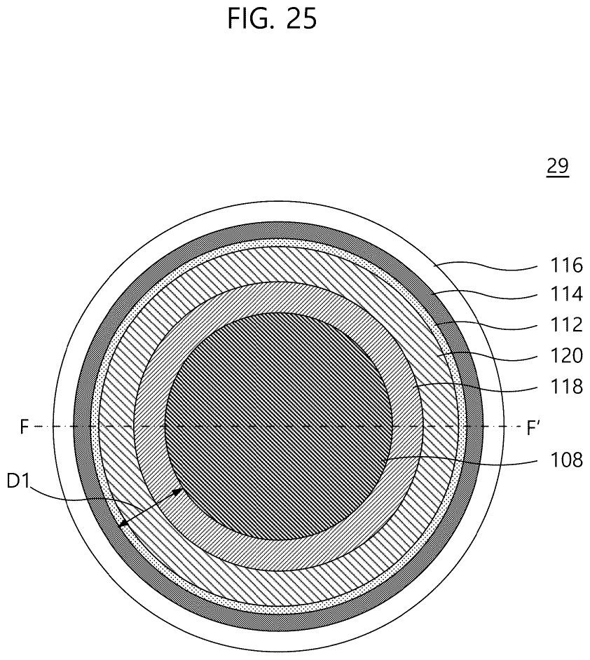

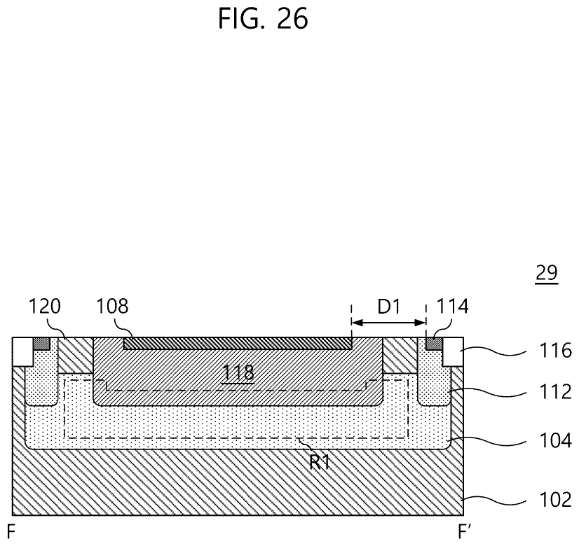

FIG. 25 is a plan view of a single photon detection device according to an exemplary embodiment. FIG. 26 is a cross-sectional view corresponding to line F-F′ of the single photon detection device of FIG. 25. For brevity of description, differences from those described with reference to FIGS. 23 and 24 are described.

Referring to FIGS. 25 and 26, a single photon detection device 29 may be provided. Unlike the description with reference to FIGS. 23 and 24, the sub-substrate region 120 may be provided between the relief region 112 and the third well 118. The sub-substrate region 120 may surround the third well 118. The sub-substrate region 120 may have the same conductivity type as the substrate region 102. The sub-substrate region 120 may have substantially the same doping concentration as the substrate region 102. For example, the doping concentration of the sub-substrate region 120 may be 1×10¹⁴ to 1×10¹⁸ cm⁻³. The sub-substrate region 120 may extend from the top surface of the single photon detection device 29 to a certain depth. For example, the bottom surface of the sub-substrate region 120 may be located at a height between the top surface and the bottom surface of the third well 118. In one example, the sub-substrate region 120 may be a region above the substrate region 102 where ions are not implanted in the ion implantation process for forming the first well 104 (ie, an upper portion of the substrate).

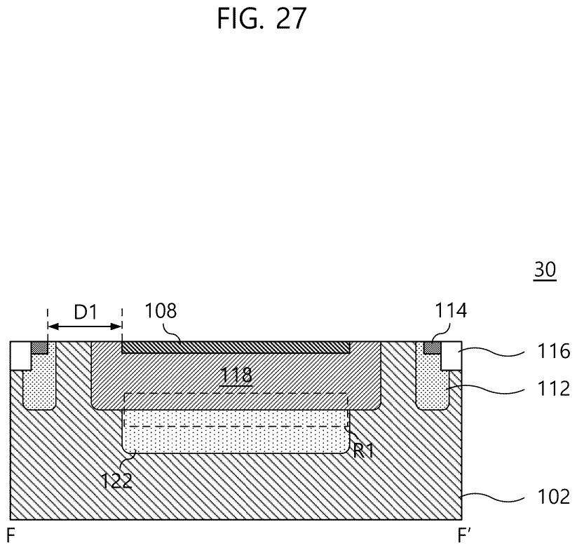

FIG. 27 is a cross-sectional view corresponding to line F-F′ of the single photon detection device of FIG. 25. For brevity of description, differences from those described with reference to FIGS. 25 and 26 are described.

Referring to FIG. 27, a single photon detection device 30 may be provided. Unlike the description with reference to FIGS. 25 and 26, a fourth well 122 may be provided instead of the first well 104. The fourth well 122 may be provided between the third well 118 and the substrate region 102. The fourth well 122 may directly contact with the third well 118 and the substrate region 102. The fourth well 122 may be provided on the bottom surface of the third well 118. For example, the width of the fourth well 122 may be smaller than that of the third well 118. The fourth well 122 may have the same conductivity type as the substrate region 102. A doping concentration of the fourth well 122 may be higher than that of the substrate region 102. For example, the doping concentration of the fourth well 122 may be 1×10¹⁶ to 1×10¹⁹ cm⁻³. The depletion region may be formed in a region adjacent to a boundary between the third well 118 and the fourth well 122.

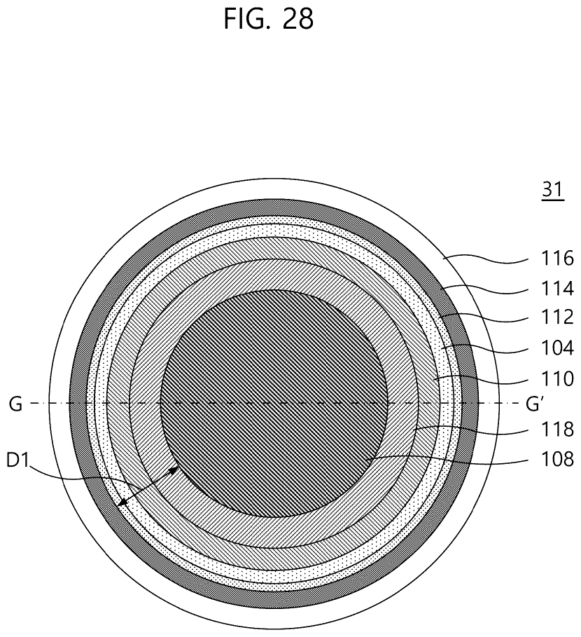

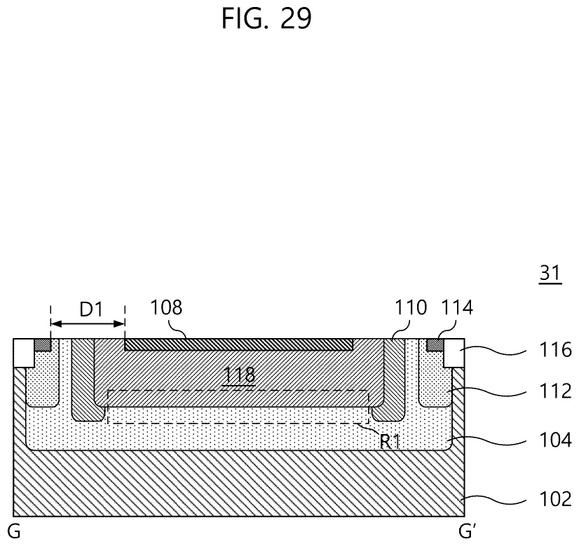

FIG. 28 is a plan view of a single photon detection device according to an exemplary embodiment. FIG. 29 is a cross-sectional view corresponding to the line G-G′ of the single photon detection device of FIG. 28. For brevity of description, differences from those described with reference to FIGS. 23 and 24 are described.

Referring to FIGS. 28 and 29, a single photon detection device 31 may be provided. Unlike the description with reference to FIGS. 23 and 24, the guard ring 110 may be provided on the side of the third well 118. The guard ring 110 may extend from a region on the side surface of the third well 118 to a region on the bottom surface of the third well 118. The bottom surface of the guard ring 110 may be located closer to the bottom surface of the first well 104 than the bottom surface of the third well 118. The guard ring 110 may have a second conductivity type. The guard ring 110 may have a lower doping concentration than that of the third well 118. For example, the doping concentration of the guard ring 110 may be 1×10¹⁵ to 1×10¹⁸ cm⁻³.

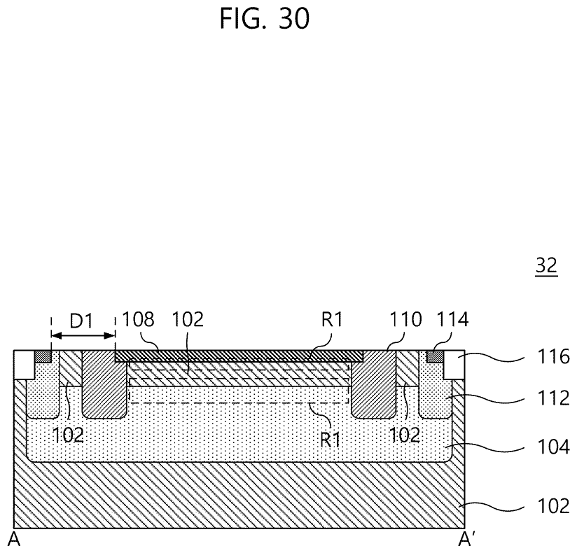

FIG. 30 is a cross-sectional view of a single photon detection device according to an exemplary embodiment. For brevity of description, content substantially the same as that described with reference to FIG. 15 may not be described.

Referring to FIG. 30, a single photon detection device 32 may be provided. Unlike the description with reference to FIG. 15, the first well 104 may be provided to be apart from the top surface of the substrate. The first well 104 may be provided to be apart from the heavily doped region 108. The top surface of the first well 104 may not directly contact with the heavily doped region 108. A substrate region 102 may be provided between the first well 104 and the heavily doped region 108. When the substrate region 102 has the same conductivity type as the heavily doped region 108 (ie, when the substrate region 102 has a second conductivity type), the depletion region R1 may be formed adjacent to the boundary between the substrate region 102 and the well 104. When the substrate region 102 has the same conductivity type as the first well 104 (ie, when the substrate region 102 has the first conductivity type), the depletion region R1 may be formed adjacent to the boundary between the substrate region 102 and the heavily doped region 108. When the substrate region 102 is an intrinsic semiconductor or is very lightly doped to approximate an intrinsic semiconductor, the depletion region R1 may be formed between the heavily doped region 108 and the first well 104.

A substrate region 102 may be provided on the first well 104 between the guard ring 110 and the relief region 112.

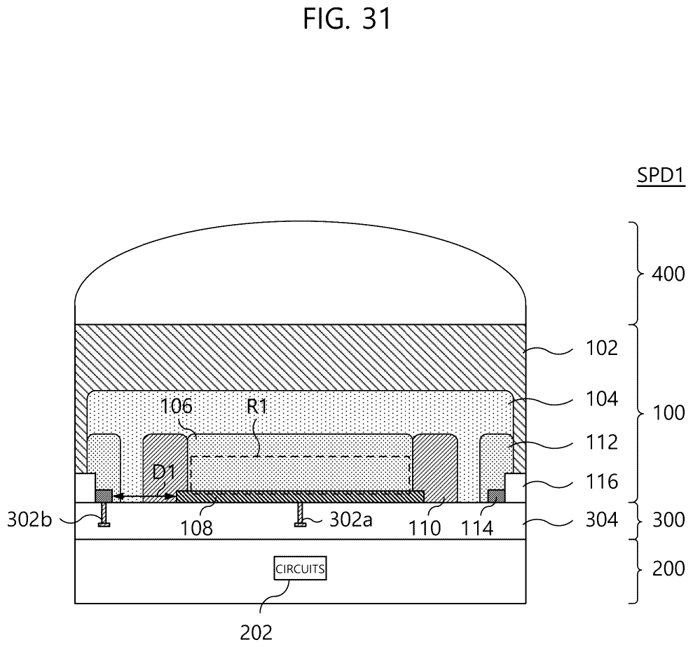

FIG. 31 is a cross-sectional view of a single photon detector according to an exemplary embodiment. For conciseness of description, content substantially the same as that described with reference to FIGS. 1 and 2 may not be described.

Referring to FIG. 31, a single photon detector SPD1 may be provided. The single photon detector SPD1 may include a single photon detection device 100, a control layer 200, a connection layer 300, and a lens unit 400. The single photon detector SPD1 may be a Back Side Illumination (BSI) type image sensor. The front side may be a surface on which various semiconductor processes are performed when manufacturing the single photon detection device 100, and the back side may be a surface disposed opposite to the front side. For example, the top and bottom surfaces of the single photon detection devices 10 to 32 of the present disclosure may be front and back sides, respectively. The back side illumination method may refer to incident light to the back side of the single photon detection device 100. A front side illumination method described below may refer to light being incident on the front side of the single photon detection device 100. The single photon detection device 100 may be substantially the same as the single photon detection device 10 described with reference to FIGS. 1 and 2. However, this is exemplary. In another example, the single photon detection device 100 may be any one of the single photon detection devices 11 to 32 described above. For convenience of description, the single photon detection device 100 is shown as a reversed top and bottom of the single photon detection device 10 shown in FIG. 2. Accordingly, the top and bottom surfaces of the single photon detection device 100 may be the back and front sides, respectively.

The control layer 200 may be provided on the front side of the single photon detection device 100. Control layer 200 may include circuit 202. For example, the control layer 200 may be a chip on which the circuit 202 is formed. Circuit 202 may include various electronic components as needed. Circuit 202 may include a quenching resistor (or quenching circuit) and a pixel circuit. A quench resistor (or quench circuit) can stop the avalanche effect and allow the single photon avalanche diode (SPAD) to detect another photon. The pixel circuit may include a reset or recharge circuit, a memory, an amplifier circuit, a counter, a gate circuit, a time-to-digital converter, and the like. Circuit 202 may also include DC-to-DC converters and other power management integrated circuits. The circuit 202 may transmit a signal to the single photon detection device 100 or receive a signal from the single photon detection device 100. Although circuit 202 is shown to be provided within control layer 200, this is exemplary. In another example, circuit 202 may be located on a semiconductor substrate on which single photon detection device 100 is formed.

The connection layer 300 may be provided between the single photon detection device 100 and the control layer 200. The connection layer 300 may include an insulating layer 304, a first conductive line 221, and a second conductive line 222. For example, insulating layer 304 may include silicon oxide (eg, SiO₂), silicon nitride (eg, SiN), silicon oxynitride (eg, SiON), or combinations thereof.

The first conductive line 302a and the second conductive line 302b may be electrically connected to the heavily doped region 108 and the contact 114, respectively. The first and second conductive lines 302a and 302b may include an electrically conductive material. For example, the first and second conductive lines 302a and 302b may include copper (Cu), aluminum (Al), tungsten (W), titanium (Ti), titanium nitride (TiN), or a combination thereof. The first and second conductive lines 302a and 302b may include a plurality of portions extending along a direction crossing or parallel to the surface of the single photon detection device 100 facing the connection layer 300. The first and second conductive lines 302a and 302b may electrically connect the heavily doped region 108 and the contact 114 to the circuit 202 of the control layer 200. One of the first conductive line 302a and the second conductive line 302b may apply a bias to the single photon detection device 100, and the other may extract a detection signal. For example, the first conductive line 302a may extract an electrical signal from the heavily doped region 108 and the second conductive line 302b may apply a bias voltage to the contact 114. In another example, the second conductive line 302b may extract an electrical signal from the contact 114 and the first conductive line 302a may apply a bias voltage to the heavily doped region 108.

The lens unit 400 may be provided on the back side of the single photon detection device 100. The lens unit 400 may focus the incident light and transmit it to the single photon detection device 100. For example, the lens unit 400 may include a microlens or a Fresnel lens. In one example, the central axis of the lens unit 400 may be aligned with the central axis of the single photon detection device 100. The central axis of the lens unit 400 and the central axis of the single photon detection element 100 pass through the center of the lens unit 400 and the center of the single photon detection element 100, respectively. The central axis of the lens unit 400 and the central axis of the single photon detection element 100 may be an imaginary axis parallel to the stacking direction of the single photon detection element 100 and the lens unit 400. In one example, the central axis of the lens unit 400 may be misaligned with the central axis of the single photon detection device 100. In one embodiment, at least one optical element may be inserted between the lens unit 400 and the single photon detection device 100. For example, the optical element may be a color filter, a bandpass filter, a metal grid, an anti-reflection coating, a 2D nanomaterial layer, or an organic material layer. In one example, an anti-reflection coating may be formed on top of the lens unit 400.

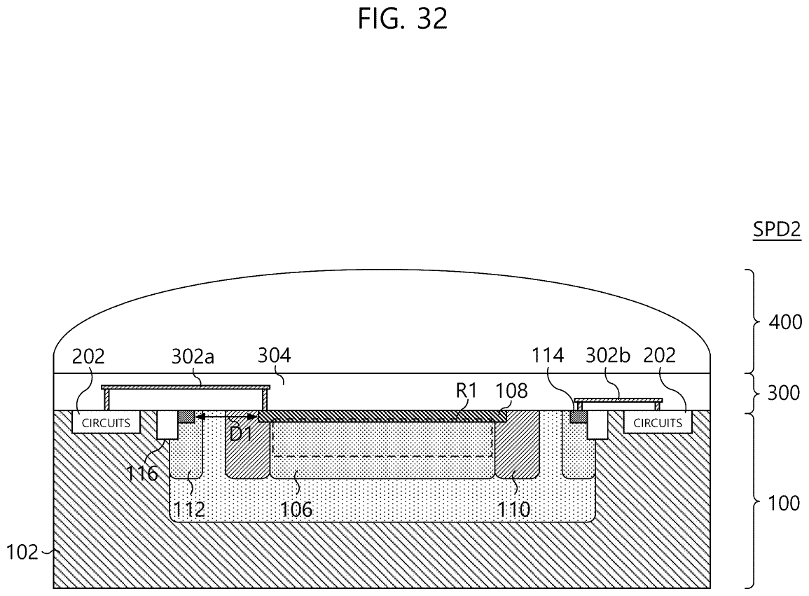

FIG. 32 is a cross-sectional view of a single photon detector according to an exemplary embodiment. For brevity of description, content substantially the same as that described with reference to FIG. 31 may not be described.

Referring to FIG. 32, a single photon detector SPD2 may be provided. The single photon detector SPD2 may be a Front Side Illumination (FSI) type image sensor. The single photon detector SPD2 may include a single photon detection device 100, a circuit 202, a connection layer 300, and a lens unit 400. The single photon detection device 100 may be substantially the same as the single photon detection device 100 described with reference to FIG. 31. For convenience of description, the single photon detection device 100 of the present disclosure is illustrated as a top-down side of the single photon detection device 100 of FIG. 31. Accordingly, the top and bottom surfaces of the single photon detection device 100 may be the front and back sides, respectively.

Circuit 202 may be disposed opposite the contact 114 with the isolation region 116 interposed therebetween. Circuit 202 may be located on top of the substrate region 102. In one example, circuit 202 may be formed on a top surface of the substrate region 102. Circuit 202 may be substantially the same as circuit 202 described with reference to FIG. 31.

The connection layer 300 may be provided on the front side of the single photon detection device 100. The connection layer 300 may include an insulating layer 304, a first conductive line 302a, and a second conductive line 302b. The insulating layer 304, the first conductive line 302a, and the second conductive line 302b may be substantially the same as the insulating layer 304, the first conductive line 302a, and the second conductive line 302b described with reference to FIG. 31, respectively.

A lens unit 400 may be provided on the connection layer 300. Therefore, unlike FIG. 31, the lens unit 400 may be disposed on the front side of the single photon detection device 100. The lens unit 400 may be substantially the same as the lens unit 400 described with reference to FIG. 31. In one embodiment, at least one optical element may be inserted between the lens unit 400 and the connection layer 300. For example, the optical element may be a color filter, a bandpass filter, a metal grid, an anti-reflection coating, a 2D nanomaterial layer, or an organic material layer. In one example, an anti-reflection coating may be formed on top of the lens unit 400.

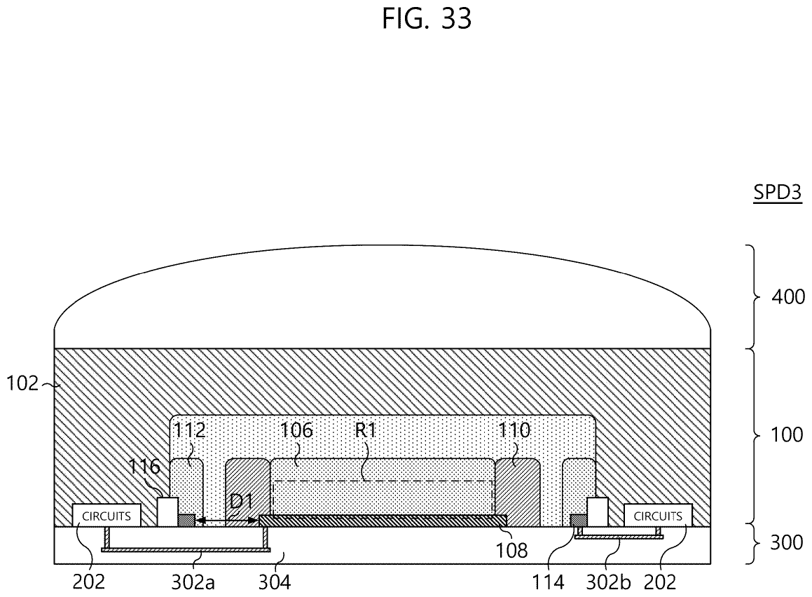

FIG. 33 is a cross-sectional view of a single photon detector according to an exemplary embodiment. For brevity of description, content substantially the same as that described with reference to FIG. 31 and with reference to FIG. 32 may not be described.

Referring to FIG. 33, a single photon detector SPD3 may be provided. The single photon detector SPD3 may be a Back Side Illumination (BSI) type image sensor. The single photon detector SPD3 may include a single photon detection device 100, a circuit 202, a connection layer 300, and a lens unit 400.

The single photon detection device 100, the circuit 202, and the connection layer 300 are substantially the same as the single photon detection device 100, the circuit 202, and the connection layer 300 described with reference to FIG. 32, respectively. For convenience of explanation, the single photon detection device 100 is illustrated as the single photon detection device 100 of FIG. 32 upside down. Accordingly, the top and bottom surfaces of the single photon detection device 100 may be the back and front sides, respectively.

As described with reference to FIG. 31, the lens unit 400 may be provided on the back side of the single photon detection device 100. The lens unit 400 may be substantially the same as the lens unit 400 described with reference to FIG. 31. In one embodiment, at least one optical element may be inserted between the lens unit 400 and the single photon detection device 100. For example, the optical element may be a color filter, a bandpass filter, a metal grid, an anti-reflection coating, a 2D nanomaterial layer, or an organic material layer. In one example, an anti-reflection coating may be formed on top of the lens unit 400.

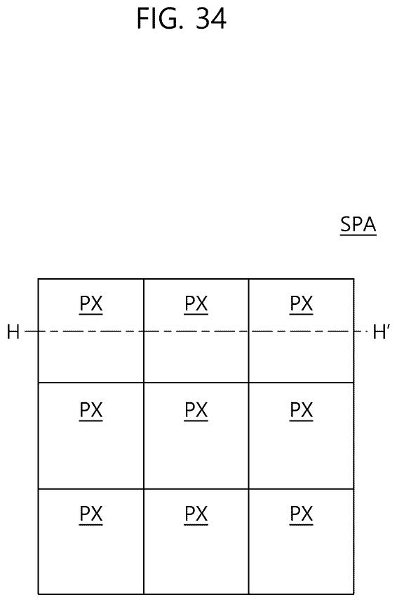

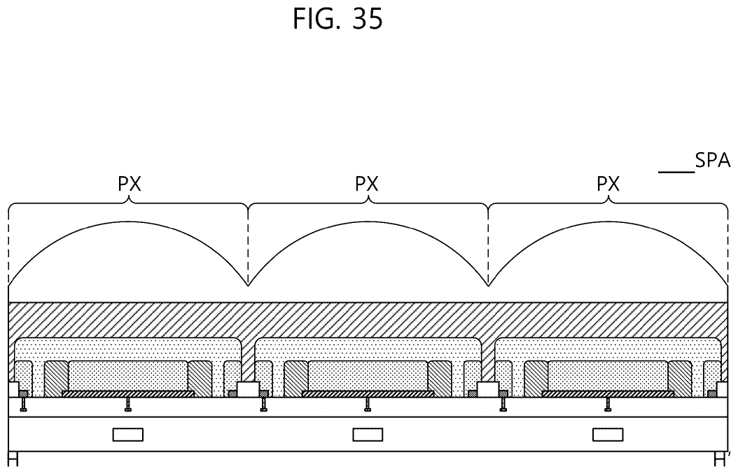

FIG. 34 is a top view of a single photon detector array according to an exemplary embodiment. FIGS. 35 to 37 are cross-sectional views taken along line H-H′ of FIG. 34. For brevity of description, content substantially the same as that described with reference to FIG. 31 may not be described.

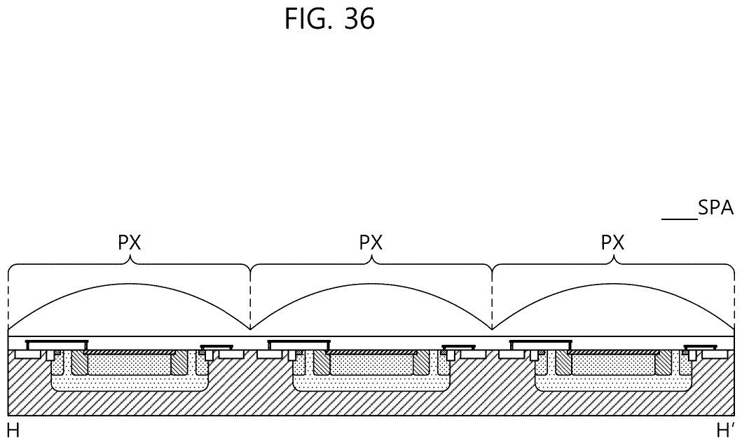

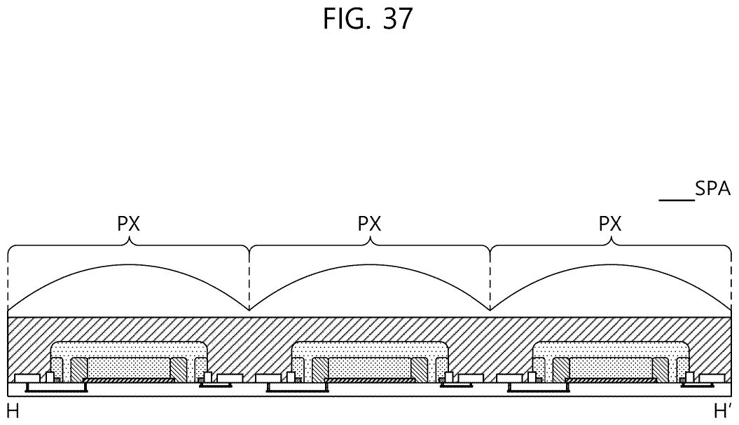

Referring to FIG. 34, a single photon detector array SPA may be provided. The single photon detector array SPA may include pixels PX arranged in two dimensions. Referring to FIG. 35, each of the pixels PX may include the single photon detector SPD1 of FIG. 31 described with reference to FIG. 31. Directly adjacent substrate regions 102 in FIG. 31, directly adjacent isolation regions 116 in FIG. 31, directly adjacent control layers 200 in FIG. 31, directly adjacent connection layers 300 in FIG. 31, and directly adjacent lens units 400 in FIG. 31 may be connected to each other. Referring to FIG. 36, each of the pixels PX may include the single photon detector SPD2 of FIG. 32 described with reference to FIG. 32. Directly adjacent substrate regions 102 in FIG. 32, directly adjacent connection layers 300 in FIG. 32, and directly adjacent lens units 400 in FIG. 32 may be connected to each other. Referring to FIG. 37, each of the pixels PX may include the single photon detector SPD3 of FIG. 33 described with reference to FIG. 33. Directly adjacent substrate regions 102 in FIG. 33, directly adjacent connection layers 300 in FIG. 33, and directly adjacent lens units 400 in FIG. 33 may be connected to each other.

In one example, a separation layer not shown may be provided between the pixels PX. The separation layer can prevent a crosstalk phenomenon in which light incident on a pixel is sensed by another pixel adjacent to the pixel. For example, the separation layer may include silicon oxide, silicon nitride, silicon oxynitride, polycrystalline silicon, a low-k dielectric material, a metal, or combinations thereof. In one example, a metal grid may be provided in a lower region of the lens unit 400 between the pixels PX. For example, the metal grid may include tungsten, copper, aluminum, or combinations thereof.

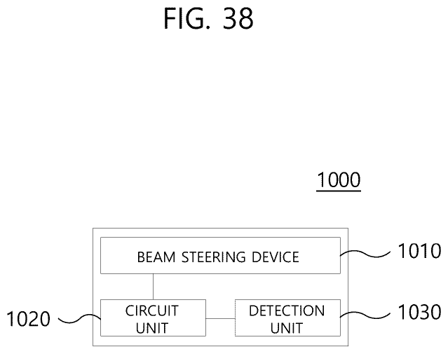

FIG. 38 is a block diagram for describing an electronic device according to an exemplary embodiment.

Referring to FIG. 38, an electronic device 1000 may be provided. The electronic device 1000 may radiate light toward a subject (not shown) and detect light reflected by the subject and returned to the electronic device 1000. The electronic device 1000 may include a beam steering device 1010. The beam steering device 1010 may adjust a direction of irradiation of light emitted to the outside of the electronic device 1000. The beam steering device 1010 may be a mechanical or non-mechanical (semiconductor) beam steering device. The electronic device 1000 may include a light source unit within the beam steering device 1010 or may include a light source unit provided separately from the beam steering device 1010. The beam steering device 1010 may be a scanning type light emitting device. However, the light emitting device of the electronic device 1000 is not limited to the beam steering device 1010. In another example, the electronic device 1000 may include a flash type light emitting device instead of the beam steering device 1010 or together with the beam steering device 1010. A flash-type light emitting device may radiate light to an area including an entire field of view at once without a scanning process.

The light steered by the beam steering device 1010 may return to the electronic device 1000 after being reflected by the subject. The electronic device 1000 may include a detector 1030 for detecting light reflected by the subject. The detector 1030 may include a plurality of light detection elements and may further include other optical members. The plurality of light detection elements may include any one of the single photon detection elements 10 to 32 described above. In addition, the electronic device 1000 may further include a circuit unit 1020 connected to at least one of the beam steering device 1010 and the detection unit 1030. The circuit unit 1020 may include a calculation unit that acquires and calculates data, and may further include a driving unit and a control unit. In addition, the circuit unit 1020 may further include a power supply unit and a memory.

Although the case where the electronic device 1000 includes the beam steering device 1010 and the detection unit 1030 in one device is shown, the beam steering device 1010 and the detection unit 1030 are not provided as one device. The beam steering device 1010 and the detection unit 1030 may be provided separately in devices. In addition, the circuit unit 1020 may be connected to the beam steering device 1010 or the detection unit 1030 through wireless communication without being wired.

The electronic device 1000 according to the above-described embodiment may be applied to various electronic devices. As an example, the electronic device 1000 may be applied to a Light Detection And Ranging (LiDAR) device. The LiDAR device may be a phase-shift type device or a time-of-flight (TOF) type device. In addition, the single photon detection elements 10 to 32 according to the embodiment or the electronic device 1000 including the same may be used in smart phones, wearable devices (glasses-type devices realizing augmented reality and virtual reality, etc.), and the Internet of Things (Internet of Things). IoT) devices, home appliances, tablet PCs (personal computers), PDAs (personal digital assistants), PMPs (portable multimedia players), navigation, drones, robots, unmanned vehicles, self-driving cars, and Advanced Drivers Assistance System (ADAS).

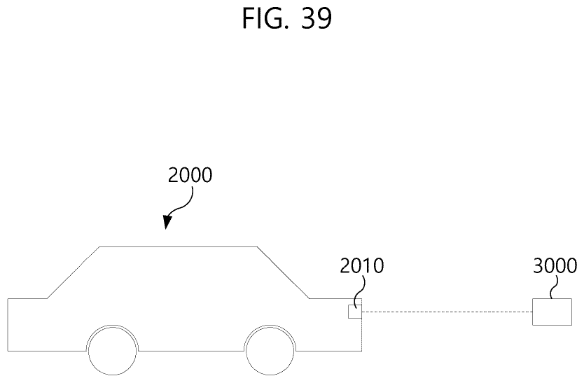

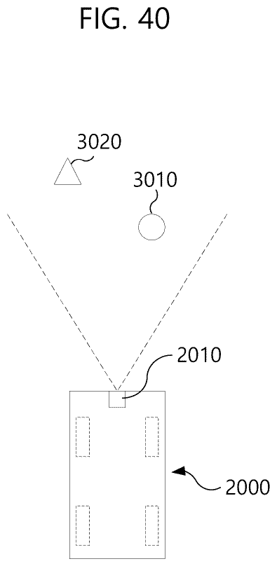

FIGS. 39 and 40 are conceptual diagrams illustrating cases in which a LiDAR device according to an exemplary embodiment is applied to a vehicle.

Referring to FIGS. 39 and 40, a LiDAR device 2010 may be applied to a vehicle 2000. Information on the subject 3000 may be obtained using a LiDAR device 2010 applied to a vehicle. The vehicle 2000 may be an automobile having an autonomous driving function. The LiDAR device 2010 may detect an object or person, ie, the subject 3000, in the direction in which the vehicle 2000 travels. The LiDAR device 2010 may measure the distance to the subject 3000 using information such as a time difference between a transmission signal and a detection signal. The LiDAR device 2010 may obtain information about a near subject 3010 and a far subject 3020 within a scanning range. The LiDAR device 2010 may include the electronic device 1000 described with reference to FIG. 38. It is illustrated that a LiDAR device 2010 is disposed in front of the vehicle 2000 to detect the subject 3000 in the direction in which the vehicle 2000 is traveling, but this is not limiting. In another example, the LiDAR device 2010 may be disposed at a plurality of locations on the vehicle 2000 to detect all subjects 3000 around the vehicle 2000. For example, four LiDAR devices 2010 may be disposed at the front, rear, and both sides of the vehicle 2000, respectively. In another example, the LiDAR device 2010 is disposed on the roof of the vehicle 2000 and rotates to detect all subjects 3000 around the vehicle 2000.

The above description of embodiments of the technical idea of the present disclosure provides examples for explanation of the technical idea of the present disclosure. Therefore, the technical spirit of the present disclosure is not limited to the above embodiments, and it is clear that many modifications and changes, such as combining and implementing the above embodiments, are possible by those skilled in the art within the technical spirit of the present disclosure.

What is claimed is:

1. A single photon detection device comprising:
a first well;
a second well provided on the first well;
a heavily doped region provided on the second well; and
a contact facing the heavily doped region,
wherein the first well, the second well, and the contact have a first conductive type,
wherein the heavily doped region has a second conductive type that is different from the first conductive type,
the region between the heavily doped region and the contact consist of semiconductor materials.

2. The single photon detection device of claim 1, wherein the distance between the heavily doped region and the contact is 0.2 [symbol] ˜2.5 [symbol] .

3. The single photon detection device of claim 1, further comprising:
a guard ring provided between the heavily doped region and the contact,
wherein the guard ring has a second conductive type and has a doping concentration lower than the heavily doped region.

4. The single photon detection device of claim 3, wherein the guard ring contacts with the heavily doped region.

5. The single photon detection device of claim 3, wherein the guard ring extends to a side surface of the second well.

6. The single photon detection device of claim 3, wherein a bottom surface of the guard ring is located at a depth between a bottom surface and an upper surface of the second well.

7. The single photon detection device of claim 3, wherein a bottom surface of the guard ring is located at the same depth as a bottom surface of the second well.

8. The single photon detection device of claim 3, wherein a bottom surface of the second well is located at a depth between an upper surface and a bottom surface of the guard ring.

9. The single photon detection device of claim 3, wherein the first well extends to a region between the guard ring and the contact.

10. The single photon detection device of claim 3, further comprising an isolation region provided on the opposite side of the guard ring with the contact interposed therebetween.

11. The single photon detection device of claim 1, wherein the heavily doped region protrudes from a side of the second well.

12. The single photon detection device of claim 1, wherein a side of the heavily doped region and a side of the second well forms a coplanar.

13. A electronic device comprising:
a single photon detection device including a first well, a second well provided on the first well, a heavily doped region provided on the second well, and a contact facing the heavily doped region,
wherein the first well, the second well, and the contact have a first conductive type,
wherein the heavily doped region has a second conductive type that is different from the first conductive type,
wherein a region between the heavily doped region and the contact consist of semiconductor materials.

14. A LiDAR device comprising:
an electronic device including a single photon detection element,
wherein the single photon detection element includes a first well, a second well provided on the first well, a heavily doped region provided on the second well, and a contact facing the heavily doped region,
wherein the first well, the second well, and the contact have a first conductive type,
wherein the heavily doped region has a second conductive type that is different from the first conductive type,
wherein the region between the heavily doped region and the contact consist of semiconductor materials.
